(19) United States
(12) Patent Application Publication
(10) Pub. No.: US 2025/0262712 A1
(43) Pub. Date: Aug. 21, 2025

(54) PROCESSING OF SCALED SIGNALS FROM IN-SITU MONITORING SYSTEM IN CHEMICAL MECHANICAL POLISHING

(71) Applicant: Applied Materials, Inc., Santa Clara, CA (US)

(72) Inventors: Kun Xu, Sunol, CA (US); David Maxwell Gage, Sunnyvale, CA (US); Priscilla Diep LaRosa, San Jose, CA (US); Harry Q. Lee, Los Altos, CA (US)

(21) Appl. No.: 18/582,534

(22) Filed: Feb. 20, 2024

(51) Int. Cl. B24B 37/013; H01L 21/321; H01L 21/66

(52) U.S. Cl. CPC B24B 37/013; H01L 21/3212; H01L 22/26

(57) ABSTRACT

A conductive layer is monitored during polishing by an in-situ eddy current monitoring system. This includes repeatedly sweeping a sensor of the in-situ eddy current monitoring system across substrate such that each sweep generates a sequence of raw signal values that provides a trace and the repeated sweeping provides a sequence of traces. For each trace is scaled to generate scaled traces extending from a same start time or start position to a same end time or end position. A sequence of average traces is generated by calculating a running average of a multiplicity of consecutive scaled traces from the sequence of scaled traces. A sequence of estimated thickness values is generated based on the sequence of average traces. A polishing endpoint is detected or a polishing parameter is modified based on the sequence of estimated thickness values.

### TECHNICAL FIELD

The present disclosure relates to in-situ monitoring during polishing of a substrate.

### BACKGROUND

An integrated circuit is typically formed on a substrate (e.g., a semiconductor wafer) by the sequential deposition of conductive, semiconductive or insulative layers on a silicon wafer, and by the subsequent processing of the layers.

One fabrication step involves depositing a filler layer over a non-planar surface, and planarizing the filler layer until the non-planar surface is exposed. For example, a conductive filler layer can be deposited on a patterned insulative layer to fill the trenches or holes in the insulative layer. The filler layer is then polished until the raised pattern of the insulative layer is exposed. After planarization, the portions of the conductive layer remaining between the raised pattern of the insulative layer form vias, plugs and lines that provide conductive paths between thin film circuits on the substrate. In addition, planarization may be used to planarize the substrate surface for lithography.

Chemical mechanical polishing (CMP) is one accepted method of planarization. This planarization method typically requires that the substrate be mounted on a carrier head. The exposed surface of the substrate is placed against a rotating polishing pad. The carrier head provides a controllable load on the substrate to push it against the polishing pad. A polishing liquid, such as slurry with abrasive particles, is supplied to the surface of the polishing pad.

One problem in CMP is determining whether the polishing process is complete, i.e., whether a substrate layer has been planarized to a desired flatness or thickness, or when a desired amount of material has been removed. Variations in the slurry composition, the polishing pad condition, the relative speed between the polishing pad and the substrate, the initial thickness of the substrate layer, and the load on the substrate can cause variations in the material removal rate. These variations cause variations in the time needed to reach the polishing endpoint. Therefore, determining the polishing endpoint merely as a function of polishing time can lead to non-uniformity within a wafer or from wafer to wafer.

In some systems, a substrate is monitored in-situ during polishing, e.g., through the polishing pad. For example, optical sensors may be used for in-situ monitoring of the substrate. Alternately (or in addition), an eddy current sensing system may be used to induce eddy currents in a conductive layer. In either case, the signal from the sensor can be used to determine the thickness of the layer on the substrate during polishing.

### SUMMARY

In one aspect, a conductive layer on a substrate is polished, and the conductive layer is monitored during the polishing with an in-situ eddy current monitoring system. This includes repeatedly sweeping a sensor of the in-situ eddy current monitoring system across substrate such that each sweep generates a sequence of raw signal values that provides a trace and the repeated sweeping provides a sequence of traces. For each trace of the sequence of traces, the trace is scaled to generate a scaled trace with each scaled trace extending from a same start time or start position to a same end time or end position, thereby generating a sequence of scaled traces. A sequence of average traces is generated by calculating a running average of a multiplicity of consecutive scaled traces from the sequence of scaled traces. A sequence of estimated thickness values is generated based on the sequence of average traces. A polishing endpoint is detected or a polishing parameter is modified based on the sequence of estimated thickness values.

Each trace includes signal values as a function of time or position, and calculating the running average is performed by averaging signal values from the multiplicity of traces having the same time or position.

Implementations may include one or more of the following features.

The sequence of estimated thickness values can define a plurality of thickness traces, and edge reconstruction can be performed on each thickness trace. Performing edge reconstruction can include processing portions of the trace corresponding to an edge of the substrate through a neural network.

In another aspect, a method of generating an underlying layer trace for use in in-situ monitoring includes bringing a calibration substrate into contact with a polishing pad on a platen. The calibration substrate includes a dielectric layer having a top surface of which is exposed. The platen and the carrier head are rotated with the calibration substrate in contact with the polishing pad, and the calibration substrate is monitored by sweeping a sensor of an in-situ eddy current monitoring system across the calibration substrate to generate a sequence of reference traces with each respective reference trace of the sequence of reference traces corresponding to a respective sweep of a sequence of sweeps by the sensor. Each reference trace includes a series of signal values. The references traces are averaged to generate an averaged trace, and the averaged trace is stored as an underlying layer trace to be subtracted from a measured trace generated by the in-situ eddy current monitoring system during polishing of a device substrate that is covered by a conductive layer.

Certain implementations can include one or more of the following advantages. An in-situ monitoring system, e.g., an eddy current monitoring system, can generate a signal as one or more sensors scan across the substrate. Noise originating from the underlying layers, e.g., metal layers and/or the silicon substrate, can be reduced, thus improving measurement accuracy. The refined signal can be used for substrate edge thickness control, endpoint control and/or closed-loop control of polishing parameters, e.g., polishing time or carrier head pressure, thus providing improved within-wafer non-uniformity (WIWNU) and water-to-wafer non-uniformity (WTWNU).

The details of one or more implementations are set forth in the accompanying drawings and the description below. Other aspects, features and advantages will be apparent from the description and drawings, and from the claims.

### BRIEF DESCRIPTION OF DRAWINGS

FIG. 1A is a schematic side view, partially cross-sectional, of a chemical mechanical polishing station that includes an eddy current monitoring system.

FIG. 1B is a schematic top view of a chemical mechanical polishing station.

FIG. 2 is a schematic graph of a static formula for determining substrate thickness based on measured signals.

FIG. 3A is a schematic top view of a substrate being scanned by a sensor head of a polishing apparatus for a single pass of the sensor.

FIG. 3B is a schematic graph of simplified signals obtained while monitoring locations on a substrate.

FIG. 4A is a schematic top view of a substrate being scanned by a sensor head of a polishing apparatus for multiple passes of the sensor.

FIG. 4B is a schematic graph of a multiplicity of measured signals without the utilization of a scan signal averaging method.

FIG. 5 is a flow-diagram of an example for a signal processing method that includes a scan averaging technique to reduce signal noise.

FIG. 6 is a schematic graph of a modified signal trace obtained by the application of the scan signal averaging method.

FIG. 7A is a schematic top view illustrating the shift in scan paths.

FIG. 7B is a schematic graph illustrating the shift in scan traces.

FIG. 7C is a schematic graph of a scaled trace by extending along the x-axis to align with another trace.

FIG. 8A is a schematic graph of a underlayer signal trace stored in a digital library.

FIG. 8B is a schematic graph of a measured signal trace before and after the subtraction of underlayer signals.

FIG. 9 is a flow-diagram of an example method of polishing a substrate.

Like reference symbols in the various drawings indicate like elements.

### DETAILED DESCRIPTION

A polishing apparatus can use an in-situ monitoring system, e.g., an eddy current monitoring system, to detect the thickness of an outer layer that is being polished on a substrate. During polishing of the outer layer, the in-situ monitoring system can determine the thickness of different regions of the layer on the substrate. The thickness measurements can be used to trigger a polishing endpoint and/or to adjust processing parameters of the polishing process in real time. For example, a substrate carrier head can selectively adjust the pressure on different regions of the backside of the substrate to increase or decrease the polishing rate at those regions. The polishing rate can be adjusted so that the layer has a substantially uniform thickness after polishing. In addition, the polishing rate can be adjusted so that polishing of the different regions completes at about the same time. Such profile control can be referred to as real time profile control (RTPC).

One problem is that an in-situ monitoring system, e.g., an eddy current monitoring system, can be subject to signal distortion due to noise originating from the underlying layers. For example, underlying metal layers with high conductivity can generate unwanted signals, which interfere with the intended eddy current signal from the conductive layer of primary interest. In particular, as compared to polishing of “blank” wafers, during polishing of a patterned wafer used for integrated circuit device fabrication, the sensor scans across regions with differing density and arrangement of metal features, resulting in variation in the signal. Moreover, this problem grows worse as the number of metal layers in the device substrate increase. In addition, because each scan of the sensor across the substrate can follow a different path, the signal varies from scan-to-scan. This heightened noise relative to the signal can introduce noise into the calculation of layer thickness. This reduces the precision of controlling polishing parameters, e.g., endpoint and/or polishing rate, and consequently result in large WIWNU and WIWNU.

However, if the system employs a scan signal averaging method to reduce the underlying signal noise, either alone or in conjunction with underlying signal subtraction approach, the apparatus can compensate for the eddy current signal distortions and improve within-wafer and wafer-to-wafer thickness uniformity.

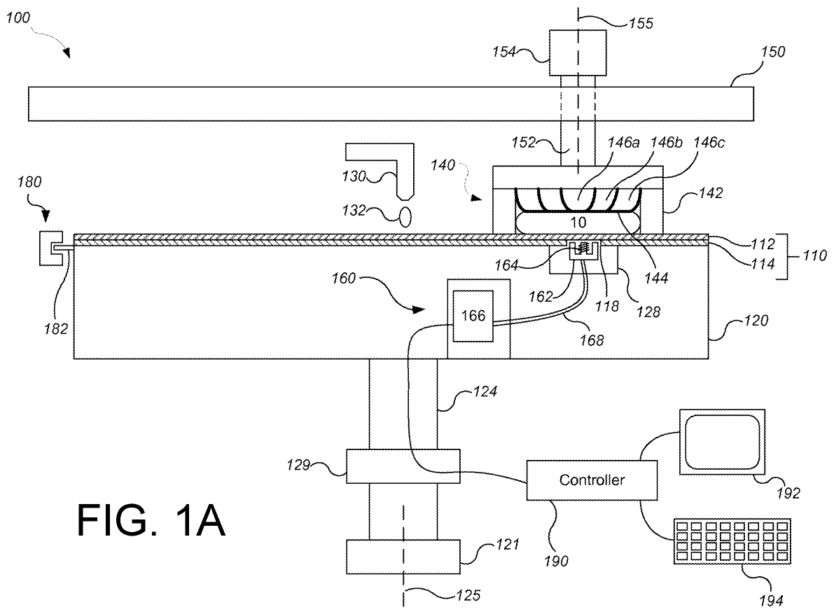

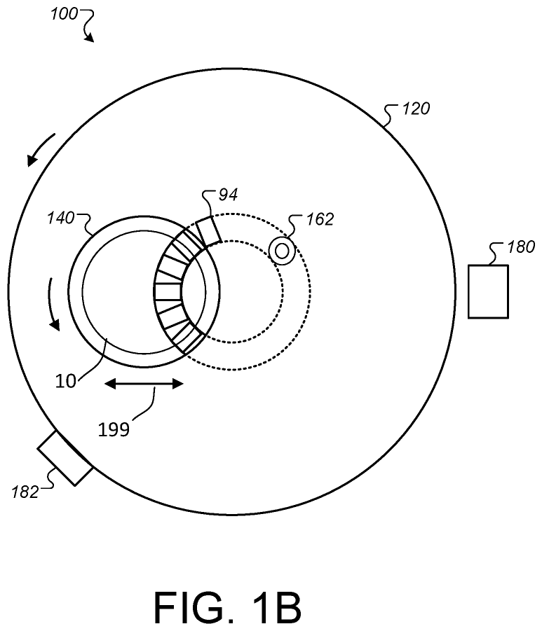

FIGS. 1A and 1B illustrate an example of a polishing apparatus 100. The polishing apparatus 100 includes a rotatable disk-shaped platen 120 on which a polishing pad 110 is situated. The platen is operable to rotate about an axis 125. For example, a motor 121 can turn a drive shaft 124 to rotate the platen 120. The polishing pad 110 can be a two-layer polishing pad with an outer polishing layer 112 and a softer backing layer 114.

The polishing apparatus 100 can include a port 130 to dispense polishing liquid 132, such as slurry, onto the polishing pad 110. The polishing apparatus can also include a polishing pad conditioner to abrade the polishing pad 110 to maintain the polishing pad 110 in a consistent abrasive state.

The polishing apparatus 100 includes at least one carrier head 140. The carrier head 140 is operable to hold a substrate 10 against the polishing pad 110. The carrier head 140 can have independent control of the polishing parameters, for example pressure, associated with each respective substrate.

In particular, the carrier head 140 can include a retaining ring 142 to retain the substrate 10 below a flexible membrane 144. The carrier head 140 also includes a plurality of independently controllable pressurizable chambers defined by the membrane, e.g., three chambers 146a-146c, which can apply independently controllable pressures to associated zones on the flexible membrane 144 and thus on the substrate 10. Although only three chambers are illustrated in FIG. 1 for ease of illustration, there could be one or two chambers, or four or more chambers, e.g., five chambers.

The carrier head 140 is suspended from a support structure 150, e.g., a carousel or a track, and is connected by a drive shaft 152 to a carrier head rotation motor 154 so that the carrier head can rotate about an axis 155. Optionally the carrier head 140 can oscillate laterally, e.g., on sliders on the carousel 150 or track; or by rotational oscillation of the carousel itself. In operation, the platen is rotated about its central axis 125, and the carrier head is rotated about its central axis 155 and translated laterally across the top surface of the polishing pad.

The polishing apparatus 100 also includes an in-situ monitoring system 160. The in-situ monitoring system 160 generates a time-varying sequence of values that depend on the thickness of a layer on the substrate. The in-situ monitoring system 160 includes a sensor head at which the measurements are generated; due to relative motion between the substrate and the sensor head, measurements will be taken at different locations on the substrate.

The in-situ-monitoring system 160 can be an eddy current monitoring system. The eddy current monitoring system 160 includes a drive system to induce eddy currents in a conductive layer on the substrate and a sensing system to detect eddy currents induced in the conductive layer by the drive system. The monitoring system 160 includes a core 162 positioned in a recess 128 to rotate with the platen, at least one coil 164 wound around a portion of the core 162, and drive and sense circuitry 166 connected by wiring 168 to the coil 164. The combination of the core 162 and coil 164 can provide the sensor head. In some implementations, the core 162 projects above the top surface of the platen 120, e.g., into a recess 118 in the bottom of the polishing pad 110.

The drive and sense circuitry 166 is configured to apply an oscillating electric signal to the coil 164 and to measure the resulting eddy current. A variety of configurations are possible for the drive and sense circuitry and for the configuration and position of the coil(s), e.g., as described in U.S. Pat. Nos. 6,924,641, 7,112,960 and 8,284,560, and in U.S. Patent Publication Nos. 2011-0189925 and 2012-0276661. The drive and sense circuitry 166 can be located in the same recess 128 or a different portion of the platen 120 or could be located outside the platen 120 and be coupled to the components in the platen through a rotary electrical union 129.

In operation the drive and sense circuitry 166 drives the coil 164 to generate an oscillating magnetic field. At least a portion of magnetic field extends through the polishing pad 110 and into substrate 10. If a conductive layer is present on substrate 10, the oscillating magnetic field generates eddy currents in the conductive layer. The eddy currents cause the conductive layer to act as an impedance source that is coupled to the drive and sense circuitry 166. As the thickness of the conductive layer changes, the impedance changes, and this can be detected by the drive and sense circuitry 166.

The CMP apparatus 100 can also include a position sensor 180, such as an optical interrupter, to sense when the core 162 is beneath the substrate 10. For example, the optical interrupter could be mounted at a fixed point opposite the carrier head 140. A flag 182 is attached to the periphery of the platen. The point of attachment and length of flag 182 is selected so that it interrupts the optical signal of sensor 180 while the core 162 sweeps beneath substrate 10. Alternatively or in addition, the CMP apparatus can include an encoder for the drive shaft 124 to determine the angular position of platen.

A controller 190, such as a general purpose programmable digital computer, receives the intensity signals from the eddy current monitoring system 160. The controller 190 can include a processor, memory, and I/O devices, as well as an output device 192 e.g., a monitor, and an input device 194, e.g., a keyboard.

The signals can pass from the eddy current monitoring system 160 to the controller 190 through the rotary electrical union 129. Alternatively, the circuitry 166 could communicate with the controller 190 by a wireless signal.

Since the core 162 sweeps beneath the substrate with each rotation of the platen, information on the conductive layer thickness is accumulated in-situ and on a continuous real-time basis (once per platen rotation). The controller 190 can be programmed to sample measurements from the monitoring system when the substrate generally overlies the core 162 (as determined by the position sensor). As polishing progresses, the thickness of the conductive layer changes, and the sampled signals vary with time. The time varying sampled signals may be referred to as traces. The measurements from the monitoring systems can be displayed on the output device 192 during polishing to permit the operator of the device to visually monitor the progress of the polishing operation.

In operation, the CMP apparatus 100 can use the eddy current monitoring system 160 to determine when the bulk of the filler layer has been removed and/or to determine when the underlying stop layer has been substantially exposed. Possible process control and endpoint criteria for the detector logic include local minima or maxima, changes in slope, threshold values in amplitude or slope, or combinations thereof.

The controller 190 may also be connected to the pressure mechanisms that control the pressure applied by carrier head 140, to carrier head rotation motor 154 to control the carrier head rotation rate, to the platen rotation motor 121 to control the platen rotation rate, or to slurry distribution port 130 to control the slurry composition supplied to the polishing pad. In addition, the computer 190 can be programmed to divide the measurements from the eddy current monitoring system 160 from each sweep beneath the substrate into a plurality of sampling zones, to calculate the radial position of each sampling zone, and to sort the amplitude measurements into radial ranges, as discussed in U.S. Pat. No. 6,399,501. After sorting the measurements into radial ranges, information on the film thickness can be fed in real-time into a closed-loop controller to periodically or continuously modify the polishing pressure profile applied by a carrier head in order to provide improved polishing uniformity.

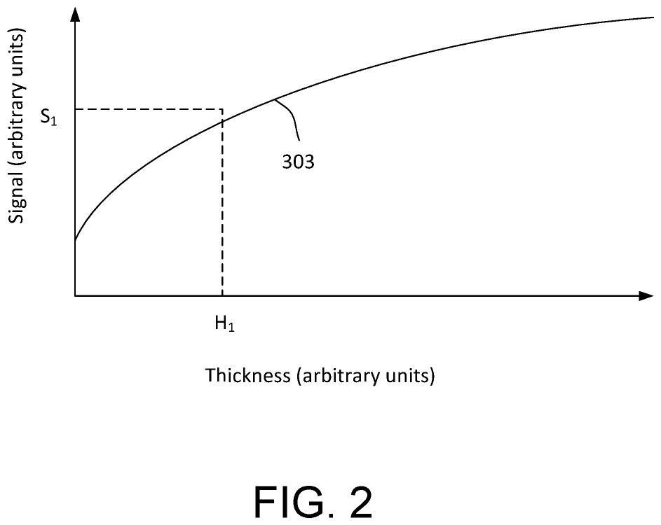

The controller 190 can use a correlation curve that relates the signal measured by the in-situ monitoring system 160 to the thickness of the layer being polished on the substrate 10 to generate an estimated measure of the thickness of the layer being polished. An example of a correlation curve 303 is shown in FIG. 2. In the coordinate system depicted in FIG. 2, the horizontal axis represents the value of the signal received from the in-situ monitoring system 160, whereas the vertical axis represents the value for the thickness of the layer of the substrate 10. For a given signal value, the controller 190 can use the correlation curve 303 to generate a corresponding thickness value. The correlation curve 303 can be considered a “static” formula, in that it predicts a thickness value for each signal value regardless of the time or position at which the sensor head obtained the signal. The correlation curve can be represented by a variety of functions, such as a polynomial function, or a look-up table (LUT) combined with linear interpolation.

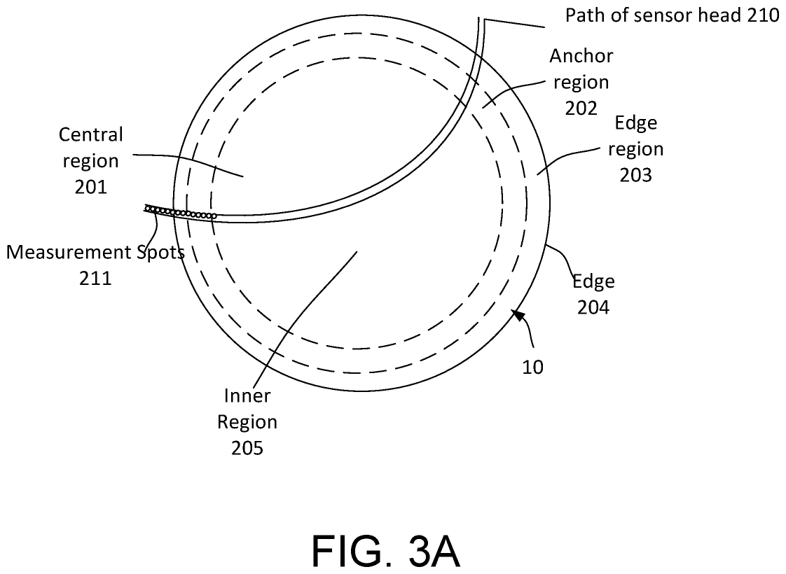

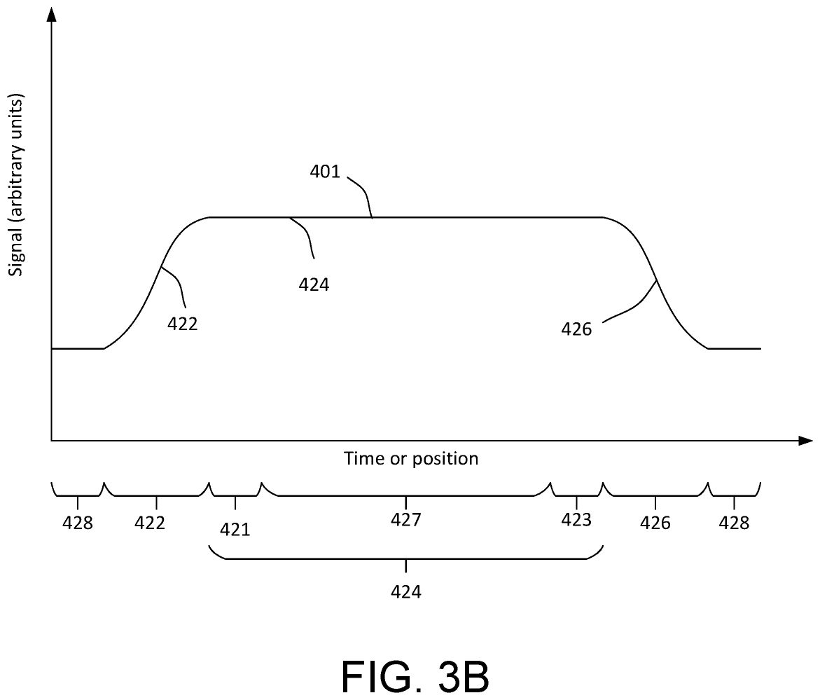

FIG. 3A shows a schematic top view of a substrate being scanned by a sensor head of a polishing apparatus for one scan path 210. Referring to FIG. 1B, as the sensor head scans across the substrate 10, the in-situ monitoring system 160 will make measurements for multiple regions, e.g., measurement spots 211, at different locations along the scan path 210 on the substrate 10. Assuming the thickness of the layer varies across the substrate, the change in the position of the sensor head with respect to the substrate 10 can result in a change in the signal from the in-situ monitoring system 160.

FIG. 3B illustrates a graph (shown for illustration of the process; no graph need be generated or displayed in operation) that shows a simplified signal 401 from the in-situ monitoring system 160 during a single pass of the sensor head below the substrate 10. For a given trace, the signal can be captured (and thus the graph can represent the signal) as a function of measurement time or of position, e.g., radial position, of the measurement on the substrate. In either case, different portions of the signal 401 correspond to measurement spots 94 at different locations on the substrate 10 scanned by the sensor head. Thus, the graph depicts, for a given location of the substrate scanned by the sensor head, a corresponding measured signal value from the signal 401. Although the signal 401 is illustrated as a continuous line, in practice the signal 401 will be composed of a sequence of individual signal values. The signal acquired from a single pass of the sensor across the substrate can be referred to as a “trace” (actual display of a trace is not necessary).

Referring to FIGS. 3A and 3B, the signal 401 includes a first portion 422 that corresponds to locations in an edge region 203 of the substrate 10 when the sensor head crosses a leading edge of the substrate 10, a second portion 424 that corresponds to locations in a central region 201 of the substrate 10, and a third portion 426 that corresponds to locations in edge region 203 when the sensor head crosses a trailing edge of the substrate 10. The signal can also include portions 428 that correspond to off-substrate measurements, i.e., signals generated when the sensor head scans areas beyond the edge 204 of the substrate 10 in FIG. 3A.

The edge region 203 can correspond to a portion of the substrate where measurement spots 94 of the sensor head overlap the substrate edge 204. The sensor head may scan these regions on its path 210 and generate a sequence of measurements that correspond to a sequence of locations along the path 210.

In the first portion 422, the signal intensity ramps up from an initial intensity (typically the signal resulting when no substrate and no carrier head is present) to a higher intensity. This is caused by the transition of the monitoring location from initially only slightly overlapping the substrate at the edge 204 of the substrate (generating the initial lower values) to the monitoring location nearly entirely overlapping the substrate (generating the higher values). Similarly, in the third portion 426, the signal intensity ramps down when the monitoring location transitions to the edge 204 of the substrate.

The second portion 424 corresponds to the monitoring location scanning the central region 201. Although the second portion 424 is illustrated as flat, this is for simplicity, and a real signal in the second portion 424 would likely include fluctuations due both to noise and to variations in the layer thickness.

A significant source of the noise can be from underlayer layer, e.g., an underlying metal layer and/or the doped silicon substrate. Without limiting to any particular theory, the magnetic field can induce eddy currents in the underlying layer, which contributes to the signal measured by the sensor head.

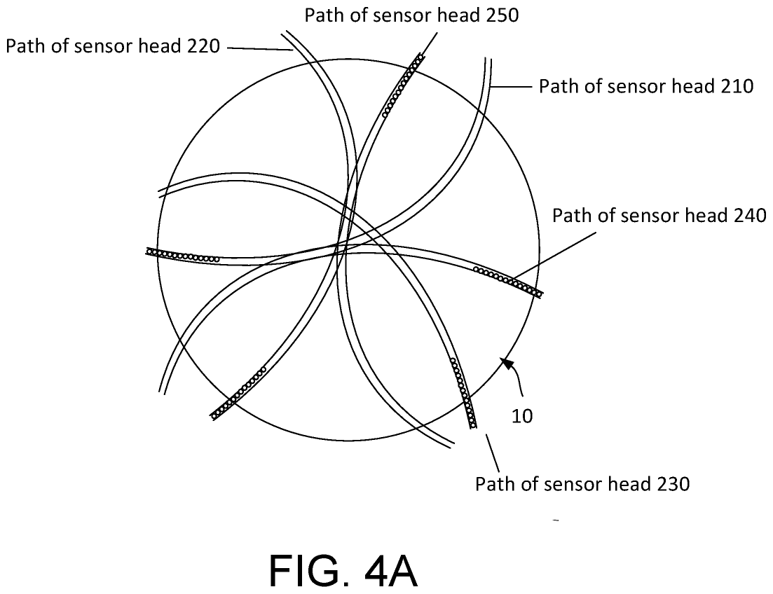

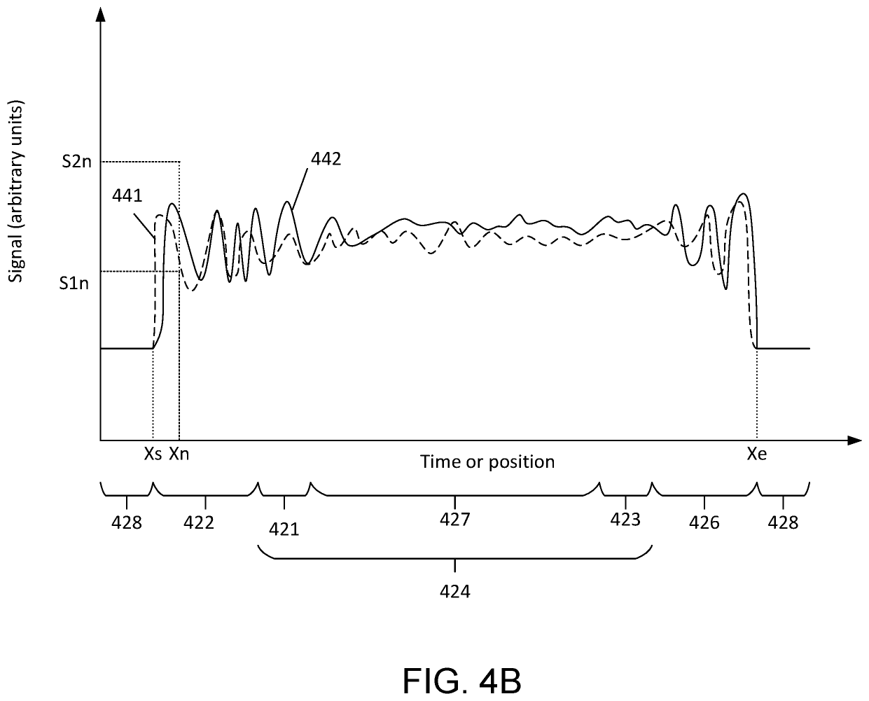

During a polishing process, one or more sensors conduct multiple scans to measure the thickness at various radial positions across the substrate 10. Due to the difference in rotation rate between the carrier head and platen, and due to the lateral oscillation of the carrier head, each individual scan may travel along a different path across the substrate. Referring to FIG. 4A, the substrate 10 is shown having been scanned by a sensor head along five distinct paths, 210, 220, 230, 240, and 250. Because the multiple scans 210-250 follow distinct paths, they cover areas with differing density and arrangement of metal features, resulting in scan-to-scan variation due to underlayer noise. Moreover, this problem grows worse as the number of metal layers in the device substrate increase.

FIG. 4B illustrates a graph (shown for illustration of the process; no graph need be generated or displayed in operation) that shows two traces 441, 442 from the in-situ monitoring system 160 acquired during two passes of the sensor head beneath the substrate 10 from two distinct scan paths. Each trace can be a function of measurement time or of position, e.g., radial position, of the measurement on the substrate. The fluctuation in a single trace 441 or 442 can be due to both variation in the thickness across the substrate of the layer being polished and underlayer noise. On the other hand, the scan-to-scan variation between these traces 441, 442 occurs because the sensor travels along two distinct scan paths, covering different arrangement of underlying metal structures.

Although only two traces, 441 and 442, are illustrated in FIG. 4B, the system can acquire three or more traces with each trace obtained from a single pass of a sensor. Multiple traces can be obtained through a single sensor with multiple scans, multiple sensors with a single scan, or multiple sensors with multiple scans.

The edge region 203 can be particularly susceptible to signal distortion for various reasons. Without limiting to any particular theory, semiconductor wafers can have a beveled edge, causing uneven pressure on the edge region 203 compared to the center region 201. Additionally, as noted above, the transition of the monitoring location can be from initially only slightly overlapping the substrate at the edge 204 of the substrate (generating the initial lower values) to the monitoring location nearly entirely overlapping the substrate (generating the higher values). This monitoring location transition can further cause edge signal distortion.

As illustrated in FIG. 4B, the portions 422 and 426 refer to the edge region of the substrate 10, which exhibited heightened noise from underlying layers. Achieving target thickness often relies on precise control of the polishing process parameters across the entire substrate. However, the presence of this heightened noise across the substrate, particularly at the substrate's edge, introduces inaccuracies in parameter control.

To address this problem, the controller 190 can incorporate a data processing program, which employs a scan averaging technique to mitigate the noise originating from the underlayers.

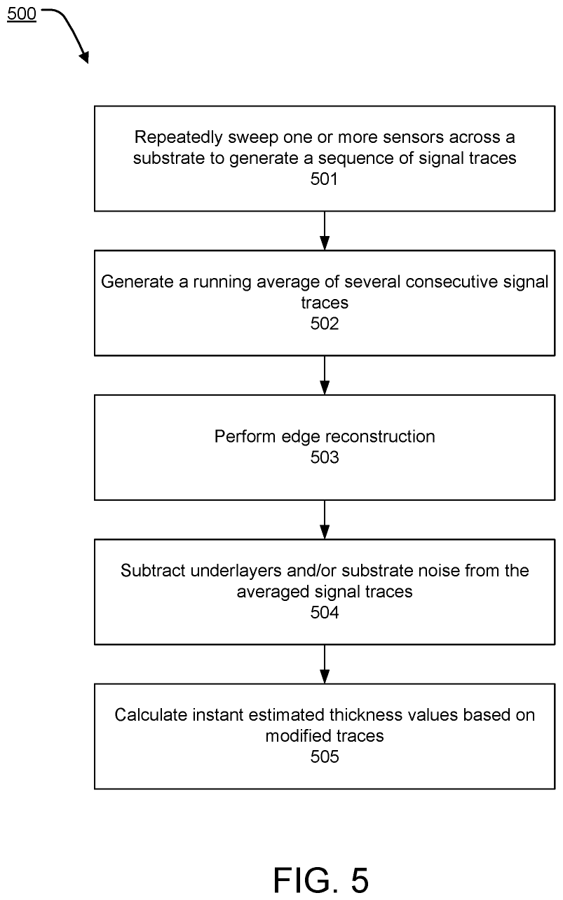

FIG. 5 is a flow-diagram of an example for a signal processing method that includes a scan averaging technique to reduce signal noise.

During CMP process, the polishing apparatus 100 repeatedly sweeps (501) one or more sensors of the in-situ monitoring system 160 across a substrate to generate a sequence of traces. Referring back to FIGS. 4A and 4B, these sensors can travel at distinct paths across the entire substrate, with each respective scan yielding a respective trace.

The controller 90 generates (502) a running average of several consecutive traces. For example, these traces can be sequentially labeled as #1, #2, #3, #4, #5, and so on. If the polishing apparatus 100 is configured to utilize five traces for the averaging method, upon completing the #5 scan, it calculates the average of the most recent five traces, encompassing #1 to #5. Upon completing the #6 scan, the apparatus recalculates the average, this time including the last five traces, ranging from #2 to #6. This process continues with each subsequent scan until the polishing process ends. The specific number of signal traces utilized for the averaging method can be predefined by data stored in the controller 90 and can be set by an operator before the polishing operation begins.

Averaging the scan signals involves computing the average signal value for corresponding positions or times. For instance, in FIG. 4B, at time or position Xn, the scan signal 441 has a signal value of S1n, while the scan signal 442 has a signal value of S2n. The averaged signal at time or position Xn is determined as Sn=(S1n+S2n)/2. This calculation process is repeated for all data points for multiple scan signal traces, resulting in an averaged scan signal trace.

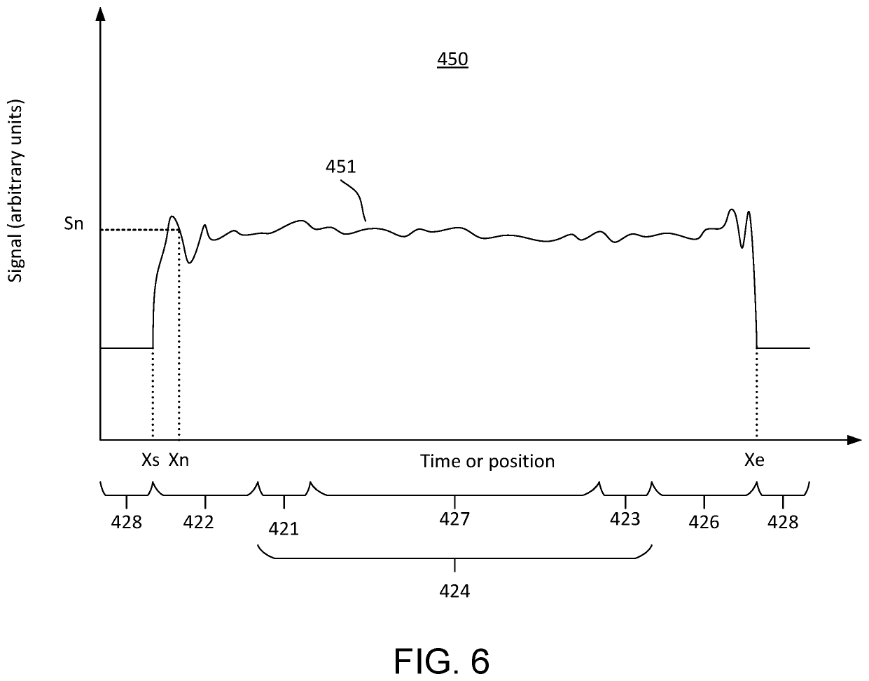

FIG. 6 illustrates a graph of an averaged scan signal trace 451 obtained by averaging the signal traces 441 and 442 in FIG. 4B. In comparison to the signals in FIG. 4B, the averaged scan signal trace 451 exhibit reduced noise fluctuations, both at the center portion 424 and the edge portions 422 and 426.

Although FIG. 4B illustrates the averaging method using just two scan signal traces, the same approach is applicable when working with two or more scan traces. For example, when employing 5 signal traces for the averaging method, the averaged signal for these 5 signal traces would involve calculating the average of all 5 signal values. More generally,

$${S}_{n} = \frac{1}{M} {\sum }_{i = 1}^{M} {S}_{ni}$$

where Sni represents the signal value at the time or position n for the i-th trace, and M is the total number of traces being averaged.

In some implementations, each signal trace may carry a different weight, and in such cases, the averaged scan signal can be expressed as follows:

$$S n = \frac{W 1 * S n 1 + W 2 * S n 2 + … + W m * S n m}{W 1 + W 2 + … + W m} = \frac{{\sum }_{i = 1}^{m} W i * S n i}{{\sum }_{i = 1}^{m} W i}$$

where i represents the numerical label of a signal trace. Wi is the weight factor for the #i signal trace at a specific time or position Xn. Sni is the signal value at Xn for the #i signal trace. m is the total number of signal traces used for calculation. Sn is the averaged signal value obtained from all m signals for the time or position Xn.

In some implementations, the number of signal traces for the running average calculation can equal or exceed the minimum number of scans necessary to encompass a substantial portion of the substrate 10. This ensures that measurements from across the entire substrate are used for generation of the average, thereby averaging out underlayer noise. On the other hand, the number of traces used cannot be too high, as this can cause latency in the detection of an endpoint by the controller. The number of traces used can be 3 to 10, depending on the process platen and head rotation speed. The chosen number of traces should be sufficient to provide one full coverage of wafer angularly.

The determination of the ‘substantiality’ of the scanned portion is not solely based on the percentage of areas scanned by one or more sensors. It encompasses various factors, including without limitation whether all four quadrants of a substrate are covered and whether the radial positions from the center to the edge of the substrate is adequately covered. As illustrated in FIG. 4A, the 5 scan traces (210, 220, 230, 240, 250) effectively covers a substantial portion of the substrate, because they collectively span all four quadrants of the substrate and extend from the center to the edge of the substrate for each quadrant.

In some implementations, the number of scans, denoted as M, required to substantially cover the substrates is given by

$$M \approx \frac{1}{2} * \frac{{R}_{1}}{{R}_{2} - {R}_{1}}$$

where R1 is the carrier head 140 rotation rate, R2 is the polishing pad 110 rotation rate. For example, when R1 is maintained at 67 rpm and R2 is maintained at 73 rpm, it takes approximately 6 scans to substantially cover the substrate 10. Under these conditions, the controller 90 can be configured to execute (502) a process for generating a running average from 6 consecutive signal traces.

The number of scans M used for the running average calculation is less than the total number of scan traces generated throughout the entire polishing process. For example, if the polishing process has a duration of approximately 2 minutes with a platen rotation rate of 80 rpm, the sensor can generate approximately 160 traces during the entire polishing procedure. However, the number of scans N chosen for the running average calculation can be, for instance, set to 6.

In some implementations, before reaching the specified number of scans, the controller 90 may calculate the running average of the initial series of available traces. For example, if the predetermined number of scans N is 3 or larger, then for scan #2, the controller 90 computes the average of the first 2 scans.

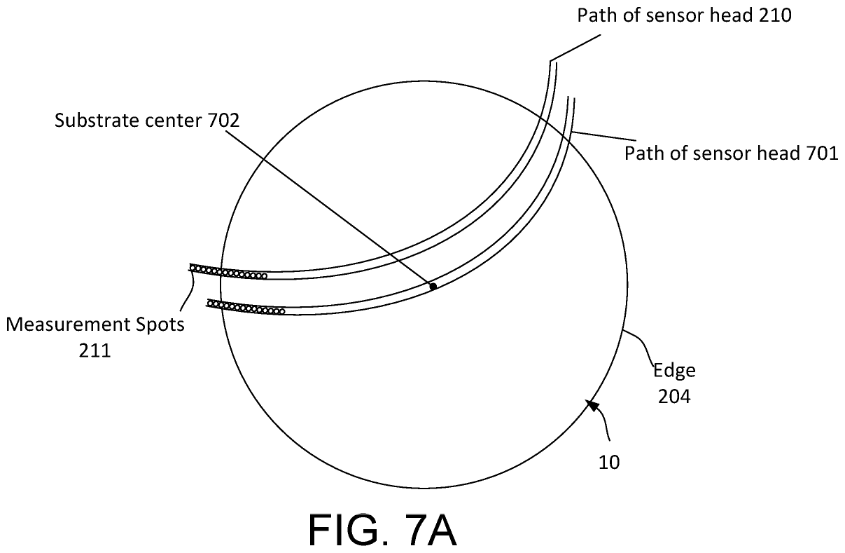

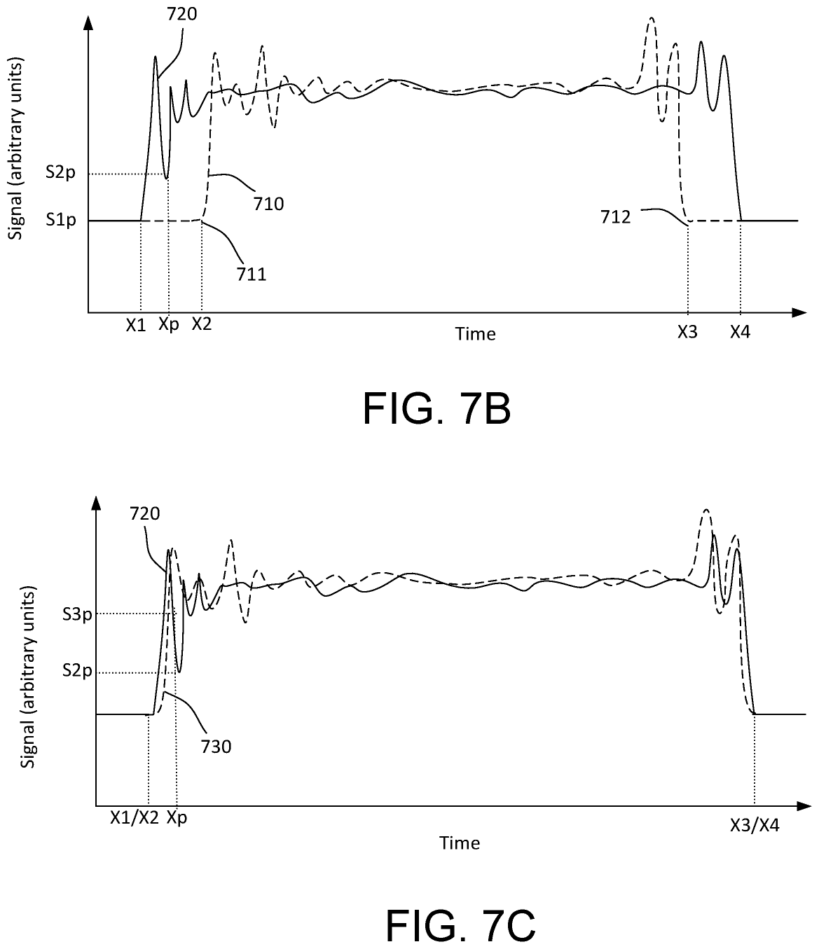

When both the carrier head 140 rotation rate and the polishing pad 110 rotation rate remain constant throughout the polishing process and the carrier head does not oscillate laterally, under ideal circumstances, each scan path will have the same arc length and take the same amount of time. However, if the carrier head 140 oscillates laterally, as illustrated in FIG. 1B, the scan path can shift radially, resulting in different scan paths having different arc lengths and taking different amounts of time. FIG. 7A illustrates an example of the displacement of between scan paths 210, 701 due to lateral oscillation of the carrier head. Because of this shift, the path 701 travels through the substrate center 702 and covers a greater distance than the path 210. Consequently, the path 701 experiences a longer scanning time compared to path 210.

Referring to FIG. 7B, the X-axis on the graph can be a measurement time or a position, e.g., radial position, of the measurement on the substrate. The scan signal trace 720 is generated by the scan path 701, starting at X1 and ending at X4. The scan signal trace 710 is generated by the scan path 210, starting at X2 and ending at X3. Due to the shorter distance covered by the scan path 210, the duration of its signal trace (X3−X2) is also shorter in comparison to the duration of the signal trace 720 (X4−X1).

Within this context, Xp is an arbitrary point located between X1 and X2. S2p signifies the measurement taken at the substrate edge region 203 for the signal trace 720, while S1p is the off-substrate measurement for the signal trace 710 at Xp (i.e., signals generated when the sensor head scans areas beyond the edge 204 of the substrate 10). This situation can introduce challenges when applying a scan averaging method at Xp, because S1p represents an off-substrate measurement that holds no meaningful value in the calculation of signals for the substrate 10.

In some implementations, the running averages is calculated by averaging signal values obtained from signal traces that share the same time or position. For example, as illustrated in FIG. 4B, both the signal trace 441 and the signal trace 442 start at the same time or position denoted as Xs and end at the same time or position denoted as Xe. Consequently, the averaged signal trace 451 (see FIG. 6), which results from averaging the trace 441 and the trace 442, maintains the same time or position as well.

In some implementations, one or more traces are scaled to ensure that each trace spans from the same starting time or position to the same ending time or position. For example, referring to FIG. 7C, the scaled signal trace 730 is derived by scaling the signal trace 710 along the x-axis in a manner that aligns its starting and ending points with those of signal trace 720, specifically matching X2 to X1 and X3 to X4. Subsequently, the averaging method is applied to both the signal trace 720 and the scaled signal trace 730. For example, at the time or position Xp, S3p represents the scaled signal value originating from the signal trace 710, and S2p represents the unscaled signal value from the signal trace 720. The averaged signal at Xp is then calculated as (S3p+S2p)/2.

In addition or alternatively, the polishing apparatus 100 can detect a leading edge of the trace and a trailing edge of the trace. For example, in FIG. 7B, the edge 711 corresponds to the leading edge of the signal trace 710, while the edge 712 corresponds to the trailing edge of the signal trace 710. The polishing apparatus 100 can be configured to detect such edges.

Referring back to FIG. 5, before or after generating (502) a running average of several consecutive signal traces, the polishing apparatus 100 can apply edge reconstruction. Edge construction refers to compensation for distortions to the signal at the substrate edge due to the scanning area only partially overlapping the substrate. In some implementations, the edge reconstruction employs a neural network, as described in U.S. Patent Publication Nos. 2018-0304435. As illustrated in FIG. 3B, the variation in the signal intensity in the portions 422, 426 is caused in part by measurement region of the sensor overlapping the substrate edge, rather than an intrinsic variation in the thickness or conductivity of the layer being monitored. Consequently, this distortion in the signal 401 can cause errors in the calculating of a characterizing value for the substrate, e.g., the thickness of the layer, near the substrate edge.

To address this problem, the controller 190 can include a neural network to generate a modified signal corresponding to one or more locations of the substrate 10 based on the measured signals corresponding to those locations. The neural network is configured to, when trained appropriately, generate modified signals that reduce and/or remove the distortion of computed signal values near the substrate edge. The system obtains estimated measures of thickness generated by the neural network based on input values that include measured signals for each location in a group of locations of the substrate.

The system then computes a measure of error between the estimated measures of thickness and the ground truth measures of thickness and updates one or more parameters of the neural network based on the measure of error. If the polishing apparatus uses such a neural network to generate modified signals based on the measured signals generated by the in-situ monitoring system, the apparatus can compensate for the distortions, e.g., reduced signal strength, at the substrate edge.

Referring back to FIG. 5, in addition to or as an alternative to edge reconstruction (503), the polishing apparatus 100 subtracts (504) underlayers and/or substrate noise from the average signal traces. The polishing apparatus 100 can be configured to incorporate a digital database comprising underlayer signals specific to each product featuring distinct underlayer layouts. These signals can subsequently be subtracted from the measured signal of the target layer to reduce undesired underlayer noise.

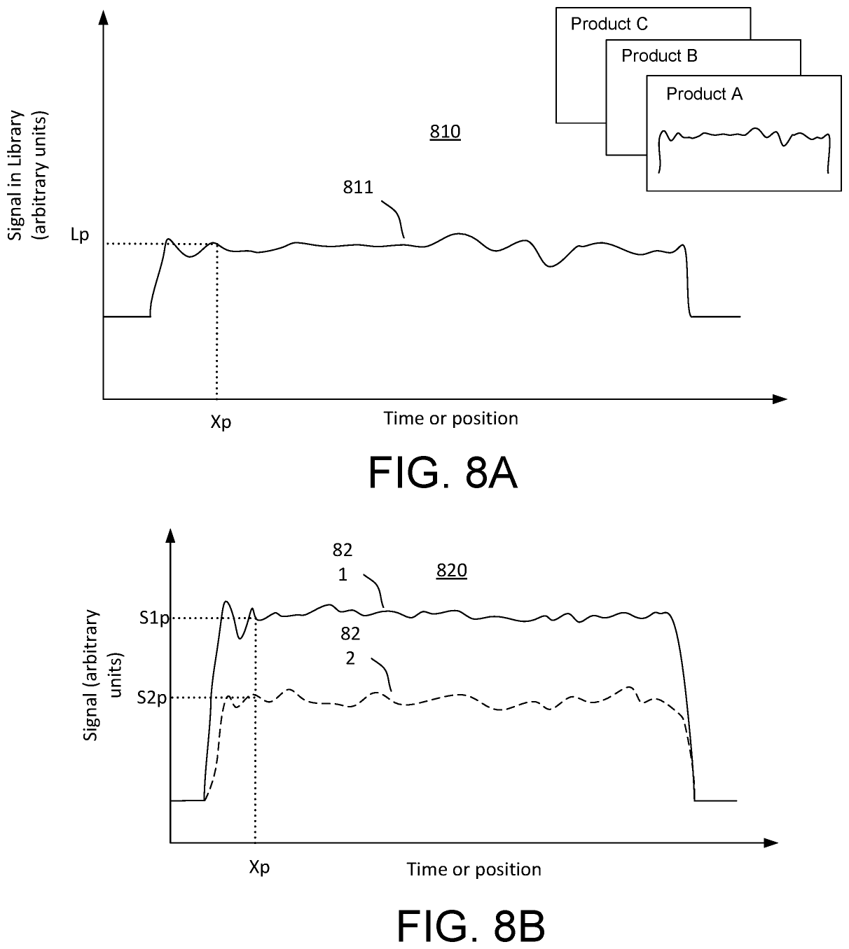

FIG. 8A is a schematic graph illustrating a signal trace 811 stored within the digital library for an arbitrary product A. FIG. 8B is a schematic graph illustrating the measured signal traces before and after underlayer noise subtraction for Product A. Specifically, signal trace 821 represents the original trace before underlayer noise subtraction, while signal trace 822 represents the modified trace following the underlayer noise subtraction process.

At any arbitrary time or position denoted as Xp, the subtraction process is given by

$$S 2 p = S 1 p - L p$$

where S1p is the signal value at Xp before the subtraction. S2p is the modified signal value at Xp after the subtraction. Lp is the underlayer library signal at Xp.

The underlayer or background signal library can be created by (1) preparing a clear or “blank” wafer that contains all or a significant portion of the underlayers beneath the layer of interest for each specific product featuring unique underlayer layout; (2) repeatedly scan one or more sensors across the substrate to produce a series of signal traces and calculate the average of these signal traces; (3) create Data Stream Interface (DSI) files for the average trace, categorizing them for each specific product; (4) store these DSI files in a digital library designated for underlayer signals. The steps mentioned above do not limit the methods available for creating the underlayer or background signal library.

Referring back to FIG. 5, the polishing apparatus 100 calculates (505) instant estimated thickness values based on modified traces. As illustrated in FIG. 2, for a given modified signal value, the polishing apparatus 100 can use the correlation curve 303 to generate a corresponding thickness value. The correlation curve 303 can be considered a “static” formula, in that it predicts a thickness value for each signal value regardless of the time or position at which the sensor head obtained the signal. The correlation curve can be represented by a variety of functions, such as a polynomial function, or a look-up table (LUT) combined with linear interpolation. A sequence of estimated thickness values can thus be generated. Each thickness profile includes thickness values as a function of radial position on the substrate 10.

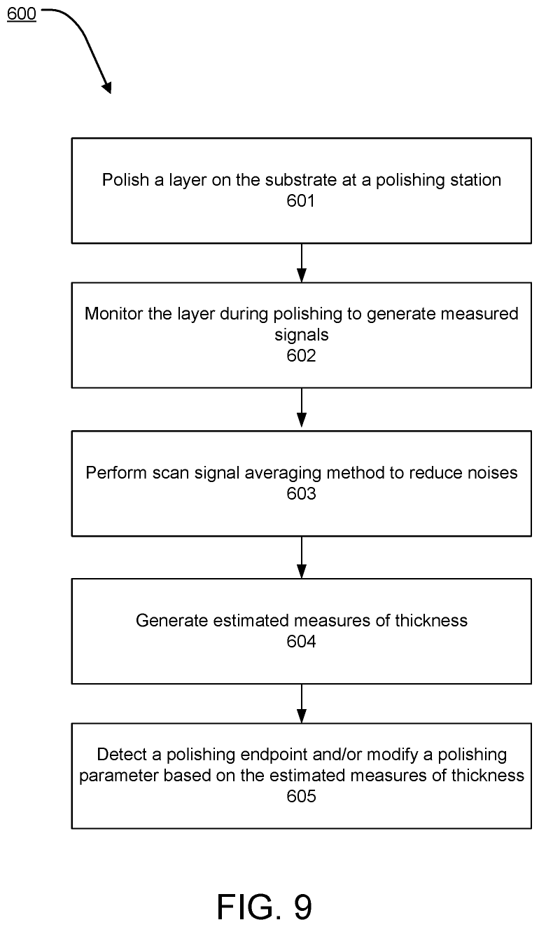

FIG. 9 is a flow-diagram of an example process 600 for polishing a substrate 10.

The polishing apparatus 100 polishes (601) a layer on the substrate 10 and monitors (602) the layer during the polishing to generate measured signal values for different locations on the layer.

The polishing apparatus 100 performs (603) scan averaging method to reduce underlayer noise. As noted above, this scan averaging method can be further combined with other signal processing methods, such as, a neutral network configured to generate modified signals that reduce the distortion of computed signal values near the substrate edge, subtraction of underlayer noises from the measured signal traces, scaling the signal trace to match position such that each trace extends along a same start time or position to a same end time or position, etc.

The polishing apparatus 100 generates (604) estimated measured of thickness, as noted above.

The polishing apparatus 100 detects (605) a polishing endpoint and/or modify a polishing parameter based on the estimated measures of thickness.

In some implementations, the process of detecting a polishing endpoint includes compensating for a delay introduced by the running average, as described in U.S. Patent Publication Nos. 2018-0079052. Many noise filtering techniques require acquisition of signal values both before and after a nominal measurement time to generate a filtered value for the nominal measurement time. Due to the need to acquire signal values after the nominal measurement time, generation of the filtered value is delayed. If the polishing endpoint is detected based on a comparison of the filtered value to the threshold value, then by the time that the endpoint has been detected, the substrate will already have been polished past the target thickness. Even if the endpoint is detected based on a projection of a fitted function to the threshold value, the filter can introduce a delay.

To mitigate this issue, adjustments can be made to either the threshold value, considering the polishing rate and the delay time associated with the running average, or the endpoint time itself by the delay time. For example, if the delay time associated with the running average method is found to be 3 s, the endpoint can be adjusted by 3 s to account for the delay. In addition or alternatively, adjustments can be made to the threshold value, such as the target thickness, by an amount equal to the product of the polishing rate and the delay time. With these adjustments, polishing can be halted closer to the target thickness, improving the precision of CMP process.

The monitoring system can be used in a variety of polishing systems. Either the polishing pad, or the carrier head, or both can move to provide relative motion between the polishing surface and the substrate. The polishing pad can be a circular (or some other shape) pad secured to the platen, a tape extending between supply and take-up rollers, or a continuous belt. The polishing pad can be affixed on a platen, incrementally advanced over a platen between polishing operations, or driven continuously over the platen during polishing. The pad can be secured to the platen during polishing, or there can be a fluid bearing between the platen and polishing pad during polishing. The polishing pad can be a standard (e.g., polyurethane with or without fillers) rough pad, a soft pad, or a fixed-abrasive pad.

Although the discussion above focuses on an eddy current monitoring system, the correction techniques can be applied to other sorts of monitoring systems, e.g., optical monitoring systems, that scan over an edge of substrate. In addition, although the discussion above focuses on a polishing system, the correction techniques can be applied to other sorts of substrate processing systems, e.g., deposition or etching systems, that include an in-situ monitoring system that scans over an edge of substrate.

A number of embodiments of the invention have been described. Nevertheless, it will be understood that various modifications may be made without departing from the spirit and scope of the invention. Accordingly, other embodiments are within the scope of the following claims.

What is claimed is:

1. A computer program product for controlling a polishing system, the computer program product residing on a non-transitory computer readable medium and comprising instructions for causing one or more computers to:
during polishing of a conductive layer on a substrate, receive a sequence of traces from a sensor of an in-situ eddy current monitoring system, each trace being a sequence of raw signal values generated by sweeping the sensor across the substrate;
for each trace of the sequence of traces, scale the trace to generate a scaled trace with each scaled trace extending from a same start time or start position to a same end time or end position, thereby generating a sequence of scaled traces;
generate a sequence of average traces by calculating a running average of a multiplicity of consecutive scaled traces from the sequence of scaled traces;
generate a sequence of estimated thickness values based on the sequence of average traces; and
at least one of detect a polishing endpoint or modify a polishing parameter based on the sequence of estimated thickness values.

2. The computer program product of claim 1, comprising instructions to detect a leading edge of the trace and a trailing edge of the trace.

3. The computer program product of claim 2, wherein each raw signal value has an associated time or position value, and the instructions to scale the trace comprise instructions to, for each raw signal value, calculate an adjusted time or position value.

4. The computer program product of claim 3, wherein the instructions to calculate the adjusted time or position value Xa comprise instructions to calculate
$$Xa = ( Xp - X 2 ) * ( X 4 - X 1 ) / ( X 3 - X 2 ) + X 1$$
where Xp is the associated time or position value, X1 is a normalized start time or position, X4 is a normalized end time or position, X2 is a start time of the raw signal value, and X3 is an end time of the raw signal value.

5. The computer program product of claim 1, comprising instructions to, for each average trace, subtract an underlying layer trace from the average trace to generate a modified trace.

6. The computer program product of claim 1, wherein the instructions to generate a sequence of estimated thickness values comprise instructions to convert signal values from a trace to thickness values using a correlation curve.

7. A method of chemical mechanical polishing, comprising:
polishing a conductive layer on a substrate;
monitoring the conductive layer during the polishing with an in-situ eddy current monitoring system, including repeatedly sweeping a sensor of the in-situ eddy current monitoring system across substrate such that each sweep generates a sequence of raw signal values that provides a trace and the repeated sweeping provides a sequence of traces;
for each trace of the sequence of traces, scaling the trace to generate a scaled trace with each scaled trace extending from a same start time or start position to a same end time or end position, thereby generating a sequence of scaled traces;
generating a sequence of average traces by calculating a running average of a multiplicity of consecutive scaled traces from the sequence of scaled traces;
generating a sequence of estimated thickness values based on the sequence of average traces; and
at least one of detecting a polishing endpoint or modifying a polishing parameter based on the sequence of estimated thickness values.

8. The method of claim 7, comprising detecting a leading edge of the trace and a trailing edge of the trace.

9. The method of claim 8, wherein each raw signal value has an associated time or position value, and wherein scaling the trace comprises, for each raw signal value, calculating an adjusted time or position value.

10. The method of claim 9, wherein calculating the adjusted time or position value Xa comprises calculating
$$Xa = ( Xp - X 2 ) * ( X 4 - X 1 ) / ( X 3 - X 2 ) + X 1$$
where Xp is the associated time or position value, X1 is a normalized start time or position, X4 is a normalized end time or position, X2 is a start time of the raw signal value, and X3 is an end time of the raw signal value.

11. A polishing system, comprising:
a platen to support a polishing pad;
a carrier head to hold a substrate in contact with the polishing pad;
a motor to generate relative motion between the carrier head and the platen;
an eddy current monitoring system to monitor the substrate during polishing and generate a sequence of raw signal values that depend on a thickness of an conductive outer layer being polished and on thickness and/or conductivity of one or more underlying layers below the outer layer; and
a controller configured to
during polishing of the conductive layer on the substrate, receiving a sequence of traces from a sensor of the in-situ eddy current monitoring system, each trace being a sequence of raw signal values generated by sweeping the sensor across the substrate,
for each trace of the sequence of traces, scaling the trace to generate a scaled trace with each scaled trace extending from a same start time or start position to a same end time or end position, thereby generating a sequence of scaled traces,
generating a sequence of average traces by calculating a running average of a multiplicity of consecutive scaled traces from the sequence of scaled traces,
generating a sequence of estimated thickness values based on the sequence of average traces, and
at least one of detecting a polishing endpoint or modifying a polishing parameter based on the sequence of estimated thickness values.

12. The system of claim 11, wherein the system is configured to detect a leading edge of the trace and a trailing edge of the trace.

13. The system of claim 12, wherein each raw signal value has an associated time or position value, and wherein the controller is configured to scale the trace by, for each raw signal value, calculating an adjusted time or position value.

14. The system of claim 13, wherein the controller is configured to calculate the adjusted time or position value Xa by calculating
$$Xa = ( Xp - X 2 ) * ( X 4 - X 1 ) / ( X 3 - X 2 ) + X 1$$
where Xp is the associated time or position value, X1 is a normalized start time or position, X4 is a normalized end time or position, X2 is a start time of the raw signal value, and X3 is an end time of the raw signal value.

15. A method of generating an underlying layer trace for use in in-situ monitoring, the method comprising:
bringing a calibration substrate into contact with a polishing pad on a platen, wherein the calibration substrate includes a dielectric layer having a top surface of which is exposed;
rotating the platen and the carrier head with the calibration substrate in contact with the polishing pad;
monitoring the calibration substrate by sweeping a sensor of an in-situ eddy current monitoring system across the calibration substrate to generate a sequence of reference traces with each respective reference trace of the sequence of reference traces corresponding to a respective sweep of a sequence of sweeps by the sensor, and wherein each reference trace includes a series of signal values;
averaging the references traces to generate an averaged trace;
storing the averaged trace as an underlying layer trace to be subtracted from a measured trace generated by the in-situ eddy current monitoring system during polishing of a device substrate that is covered by a conductive layer.

16. The method of claim 15, comprising conducting the monitoring of the calibration substrate with substantially no polishing occurring.

17. The method of claim 16, comprising flushing a polishing surface of the polishing pad with a cleaning liquid to remove slurry from the polishing surface before bringing the calibration substrate into contact with a polishing pad.

18. The method of claim 16, comprising venting a chamber in the carrier head holding the calibration substrate while the calibration substrate is in contact with the polishing pad.

19. The method of claim 15, wherein the sequence of reference traces includes 4 to 8 traces.

20. The method of claim 15, wherein scanning the scanning the sensor across the calibration substrate generates a raw signal trace, and comprising converting the raw signal trace to the reference trace using a correlation curve that relates signal values to thickness values.
